(19) United States
(12) Patent Application Publication
(10) Pub. No.: US 2007/0108546 A1
(43) Pub. Date: May 17, 2007

(54) PHOTOELECTRIC CONVERTER AND IMAGING SYSTEM INCLUDING THE SAME

(75) Inventor: Aiko Furuichi, Tokyo (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 11/559,249

(22) Filed: Nov. 13, 2006

(30) Foreign Application Priority Data
Nov. 15, 2005 (JP) 2005-330142

(51) Int. Cl. H01L 31/06

(52) U.S. Cl. 257/462

(57) ABSTRACT

A photoelectric converter includes a substrate, photoelectric converting elements formed in the substrate and each having a light-receiving surface, an antireflection film arranged above at least a part of the light-receiving surface of each photoelectric converting element, an element isolation region including an insulator, a plurality of transistors including read transistors configured to read electric charges of the photoelectric converting elements, an interlayer insulating film arranged above the photoelectric conversion elements and the read transistors, and contacts electrically connected to active regions of the transistors. The antireflection film is arranged above the element isolation region and the active region connected to each contact. The antireflection film serves as an etch stop film when the interlayer insulating film is etched.

### BACKGROUND OF THE INVENTION

1. Field of the Invention

The present invention relates to a photoelectric converter including photoelectric converting elements and semiconductor elements that are different from the photoelectric converting elements. More particularly, the invention relates to a photoelectric converter in which reflection at the light-receiving surfaces of the photoelectric converting elements is reduced.

2. Description of the Related Art

In a photoelectric converter, photoelectric converting elements, circuits for amplifying signals from the photoelectric converting elements, and the like are one-dimensionally or two-dimensionally arrayed on a substrate. As photosensors which convert optical signals into electrical signals, photoelectric converters are, for example, used as control photosensors in various photoelectric converting apparatuses and mounted on digital cameras, video cameras, copiers, facsimile machines, and the like.

In the photoelectric converters, it is necessary to allow light to enter photoelectric converting elements efficiently. Consequently, the surfaces of the photoelectric converting elements are coated with an antireflection film, such as a silicon nitride film, so that the surfaces are protected and reflection at the surfaces is minimized. Japanese Patent Laid-Open Nos. 63-014466 and 2000-236080 (corresponding to U.S. Pat. No. 6,525,356) each disclose a photoelectric converter in which an antireflection film, such as a silicon nitride film, is disposed on the surfaces of the photoelectric converting elements.

Recently, pixel density has been increasing in photoelectric converters. As a result, the size of photoelectric converters has been decreasing, and the light reception area of the photoelectric converting elements and the area of active regions of transistors constituting circuits have been decreasing. The area of element isolation regions for isolating photoelectric converting elements from transistors and the area of element isolation regions between transistors have also been decreasing. In the past, locally oxidized films, such as LOCOS films, were used for element isolation. However, with the reduction in size of photoelectric converters, the percentage of the area taken up by the element isolation regions in the total area is increasing excessively, thus causing problems. Consequently, there is a tendency to use a shallow trench isolation (STI) technique in which a buried insulating film is formed in trenches provided in a semiconductor substrate to form element isolation regions.

Japanese Patent Laid-Open No. 10-012733 discloses that, in a semiconductor device having the STI structure, because of misalignment during the formation of contact holes 524, element isolation regions are partially damaged by etching. As shown in FIG. 5, the patent document discloses a semiconductor device in which an etch stop film 518 is disposed on at least a part of a buried insulating film (isolation film) 517 in the element isolation region when the buried insulating film 517 is formed, and then an interlayer insulating film 522 is deposited. Reference numeral 511 represents a semiconductor substrate, and reference numeral 521 represents a source region. A gate electrode 519 is disposed on the semiconductor substrate 511 with an insulating film 512 therebetween. Reference numeral 516 represents an oxide film formed inside the trench. Reference numeral 526 represents a conductor buried in the contact hole 524, and reference numeral 525 represents an adhesion layer therefor.

Because of the presence of the etch stop film 518, the isolation film 517 in the trench 515 is not removed by etching. However, to fabricate the structure in which the etch stop film is disposed on at least a part of the buried insolating film in the element isolation region, a complicated process is required. Specifically, since the etch stop film is not provided at the position where a contact is formed, the patterning process becomes complicated.

Furthermore, in a photoelectric converter, it is necessary to form an antireflection film. In such a case, since the antireflection film and the etch stop film are separately formed, the fabrication process becomes further complicated.

### SUMMARY OF THE INVENTION

The present invention is directed to a photoelectric converter in which the process of forming an antireflection film and an etch stop film can be simplified.

According to an aspect of the present invention, a photoelectric converter includes a substrate, photoelectric converting elements formed in the substrate and each having a light-receiving surface, an antireflection film arranged above at least a part of the light-receiving surface of each photoelectric converting element, an element isolation region including an insulator, a plurality of transistors including read transistors configured to read electric charges of the photoelectric converting elements, an interlayer insulating film arranged above the photoelectric conversion elements and the read transistors, and contacts electrically connected to active regions of the transistors. The antireflection film is arranged above the element isolation region and the active region connected to each contact. The antireflection film serves as an etch stop film when the interlayer insulating film is etched.

According to another aspect of the present invention, a photoelectric converter includes a substrate, photoelectric converting elements formed in the substrate and each having a light-receiving surface, an antireflection film arranged above at least a part of the light-receiving surface of each photoelectric converting element, an element isolation region including an insulator, a plurality of transistors including read transistors configured to read electric charges of the photoelectric converting elements, an interlayer insulating film arranged above the photoelectric conversion elements and the read transistors, and contacts electrically connected to active regions of the transistors. The antireflection film is arranged above the element isolation region and the active region connected to each contact. An opening for each contact is formed in the interlayer insulating film using the antireflection film as an etch stop film.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a cross-sectional view showing a substantial part of a photoelectric converter according to a first embodiment.

FIG. 2 is a cross-sectional view showing a substantial part of a photoelectric converter according to a second embodiment.

FIGS. 3A to 3E are cross-sectional views showing steps in a method for fabricating the photoelectric converter according to the second embodiment.

FIG. 4A is a circuit diagram showing an example of a circuit of a photoelectric converter, and FIG. 4B is a plan layout view of a pixel area shown in FIG. 4A.

FIG. 5 is a cross-sectional view showing a relationship between misalignment of a contact hole and an etch stop film.

FIG. 6 is a block diagram of a video camera to which a photoelectric converter is applied.

The accompanying drawings, which are incorporated in and constitute a part of the specification, illustrate embodiments of the invention and, together with the description, serve to explain the principles of the invention.

### DESCRIPTION OF THE EMBODIMENTS

In a photoelectric converter of the present invention, an antireflection film is arranged above the light-receiving surface of each photoelectric converting element, an element isolation region including an insulator, and the active region connected to each contact. The antireflection film serves as an etch stop film during etching when the contacts are formed. By disposing the antireflection film so as to cover a part of the element isolation region and a part of the active region in which the contact is formed, it is possible to respond suitably to the misalignment. In particular, the antireflection film can be disposed so as to cover the boundary between the active region in which the contact is formed and its adjacent element isolation region. Furthermore, the antireflection film can be arranged at the periphery of the photoelectric converting elements. Since noise due to etching can be reduced, it is possible to decrease the influence of noise on the photoelectric converting elements.

In such structure, it is possible to simultaneously provide the antireflection film and an etch stop film used when the contact hole is formed by etching an interlayer insulating film. Thus, it is possible to simplify the process for forming the antireflection film and the etch stop film.

The antireflection film can be composed of a silicon nitride film having high hydrogen content. In a photoelectric converter, it is necessary to suppress the degradation of image quality due to dark current. Dark current is generated from the interface state near the gate of MOS transistor connected to a photoelectric converting element and the interface state near the photoelectric converting element itself. Hydrogen is supplied to the semiconductor substrate from the silicon nitride film having high hydrogen content, and thus the interface state is terminated with hydrogen. Consequently, the interface state is reduced, and dark current can be reduced. Accordingly, the image quality of the photoelectric converter can be further improved.

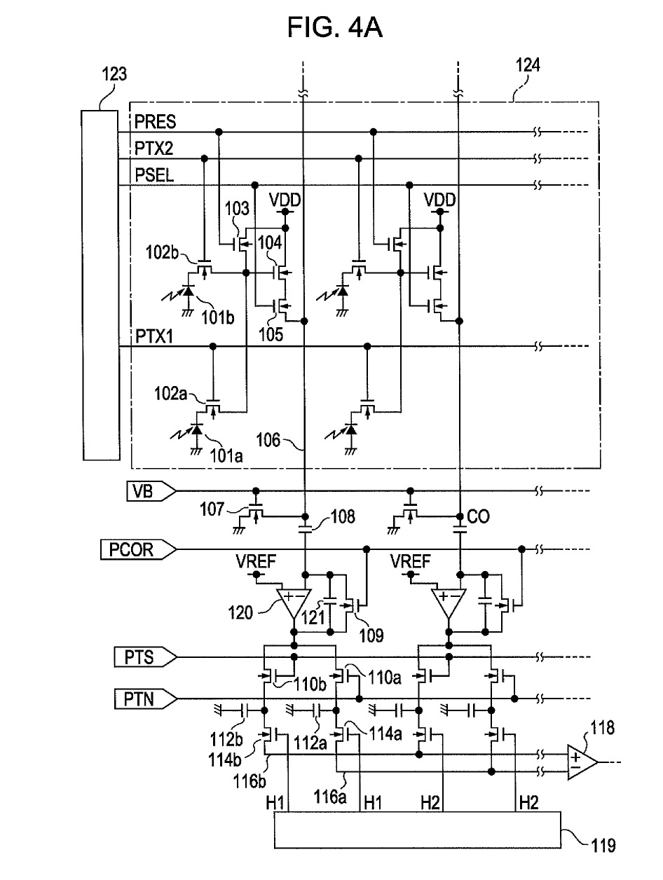

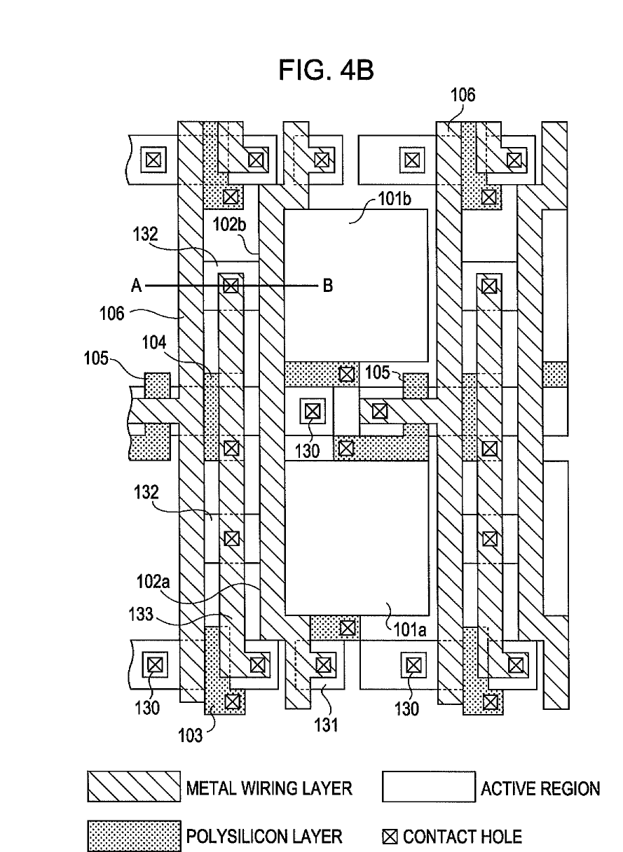

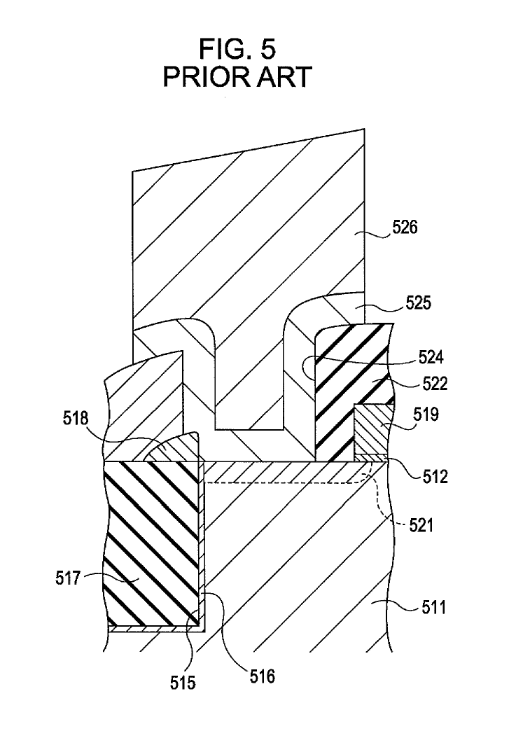

FIG. 4A shows an example of a part of a circuit of a photoelectric converter applicable in the present invention, and FIG. 4B is a plan layout view of a pixel area shown in FIG. 4A. Each will be described briefly below.

In FIG. 4A, reference numeral 124 represents a pixel area. Reference numerals 101a and 101b each represent a photoelectric converting element, and reference numerals 102a and 102b each represent a transfer MOS transistor which transfers the electric charges of the photoelectric converting element. Reference numeral 103 represents a reset MOS transistor, reference numeral 104 represents an amplification MOS transistor which amplifies and outputs the electric charges to a signal line 106. The reset MOS transistor resets the photoelectric converting elements 101a and 101b and the gate electrodes of the amplification MOS transistors 104. Reference numeral 105 represents a selection MOS transistor which controls reading out to the signal line. The transfer transistor, the reset transistor, the amplification MOS transistor, and the selection MOS transistor serve as read transistors. In the photoelectric converter shown in FIG. 4A, the transistors 103, 104, and 105 serving as the read transistors are shared by two photoelectric converting elements.

Furthermore, each signal line 106 is provided with a load MOS 107, which, together with the amplification MOS transistor in the pixel area, forms a source follower circuit. Furthermore, each signal line 106 is provided with a clamp circuit including a clamp capacitor 108 and a clamp switch 109, a column amplifier portion including an amplifier 120 and a feedback capacitor 121, and a signal holding portion including capacitors 112a and 112b. Reference numerals 110a and 110b represent switches (MOS transistors) which are used when signals from the column amplifier portion are input to the capacitors 112a and 112b, respectively. Signals are output from the capacitors 112a and 112b through switches 114a and 114b to horizontal signal lines 116a and 116b, respectively, and the signals are output from a differential amplifier 118. Reference numerals 123 and 119 each represent a scanning circuit.

FIG. 4B is a plan layout view which schematically shows a part of the pixel area shown in FIG. 4A. The reference numerals correspond to those in FIG. 4A. Photoelectric converting elements 101a and 101b are arrayed, and electric charges of the photoelectric converting elements are transferred to drain regions 132 of transfer MOS transistors 102a and 102b. Gate electrodes of the transfer MOS transistors are arranged below the metal wiring. The drain regions of the transfer MOS transistors electrically float when the electric charges of the photoelectric converting elements are transferred, thus which are floating diffusion regions. The floating diffusion regions are connected to the gate electrodes of the amplification MOS transistors via wiring 133. In FIG. 4B, a contact is indicated by a square. Reference numeral 130 represents a grounded contact and reference numeral 131 represents a semiconductor region connected to a power supply. Note that this plan layout view is an example.

Exemplary embodiments of the present invention will be described below. However, it is to be understood that the present invention is not limited thereto. Appropriate changes and combinations can be made within the scope of the invention without departing from the spirit thereof.

### First Embodiment

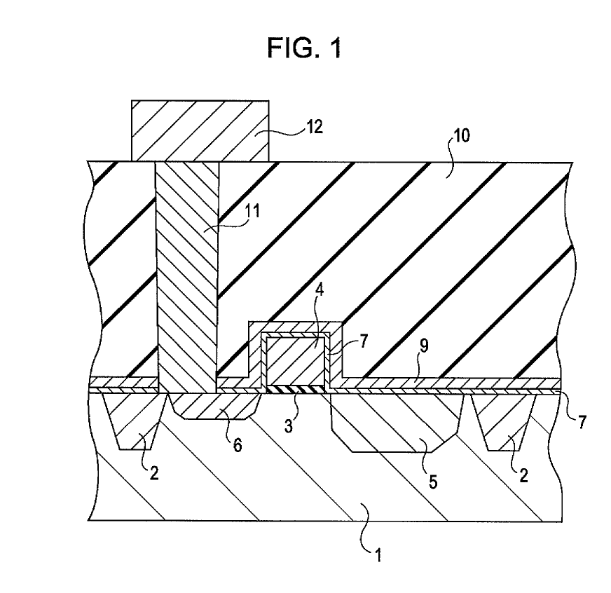

FIG. 1 is a cross-sectional view showing a substantial part of a photoelectric converter according to a first embodiment. This cross-sectional view corresponds to that taken along the line A-B in FIG. 4B.

FIG. 1 shows a substantial part of a photoelectric converter in which a photodiode and MOS transistor are disposed. In the actual photoelectric converter, wiring layers connected to a gate electrode 4 and the like are provided, which are not shown in FIG. 1.

In the photoelectric converter according to this embodiment, on the surface of a silicon substrate 1, which is, for example, a first-conductivity-type semiconductor substrate, a semiconductor region 5 of a conductivity type opposite the first conductivity type (i.e., second conductivity type) is disposed. The second-conductivity-type semiconductor region 5 has the same conductivity type as that of signal electric charges and accumulates signal electric charges. The semiconductor region 5 constitutes a photoelectric converting element. In order to isolate the photoelectric converting element from other circuit elements, an element isolation region 2 having a shallow trench isolation (hereinafter referred to as “STI”) structure is disposed between the second-conductivity-type semiconductor region 5 and other circuit elements to be separated. The STI is formed by disposing an insulator, such as a silicon oxide film, in a trench provided in the silicon substrate 1. The silicon substrate 1 and the second-conductivity-type semiconductor region 5 form a pn junction constituting a photodiode, which corresponds to a light-receiving portion of the photoelectric converter. A gate electrode 4 composed of polysilicon, for example, is disposed on a gate insulating film 3. A second-conductivity-type semiconductor region (drain region) 6 is disposed on the surface of the silicon substrate 1 at a position opposite the second-conductivity-type semiconductor region 5 with the position where the gate electrode 4 is formed therebetween. The element isolation region 2 may have a LOCOS structure or the like. The LOCOS structure is also an element isolation structure including an insulator.

A silicon oxide film 7 is disposed on the surface of the silicon substrate 1 (including the surfaces of the element isolation region 2, the second-conductivity-type semiconductor region 5, and the drain region 6) excluding the position where the gate insulating film 3 is formed. The silicon oxide film 7 can be provided on the top face and the side face of the gate electrode 4.

A silicon nitride film 9 is disposed so as to cover the exposed surface of the silicon oxide film 7 and the upper surface of the gate electrode 4. An interlayer insulating film 10 is disposed on the silicon nitride film 9, and a contact 11 is provided. The contact 11 has a plug composed of a conductive material. The plug electrically connects an upper wiring layer 12 to the gate electrode 4, the drain region 6, and the like.

The silicon nitride film 9 functions as an etch stop film during the formation of the contact hole and is less susceptible to etching than the interlayer insulating film composed of silicon oxide or the like. The silicon nitride film 9 also serves as an antireflection film at the light-receiving surface of the photoelectric converting element. The antireflection film is a film placed to reduce reflection at the light-receiving surface of the photoelectric converting element. Accordingly, the silicon nitride film 9 covers at least a part of the light-receiving surface of the photoelectric converting element and a part of the element isolation region 2, and also covers a part of the active region in which the contact hole is formed. The contact hole is an opening provided in the interlayer insulating film. The active region is a region isolated by the element isolation region, in which various elements are disposed, or the active region constitutes a part of an element. For example, the active region includes the drain region and the source region of a transistor. In this embodiment, the active region in which the contact is provided corresponds to the drain region 6 which is the floating diffusion region near the photoelectric converting element.

The silicon nitride film 9 can be formed by single-wafer thermal CVD or plasma CVD. The silicon nitride film 9 can have a hydrogen (H) concentration of 1×10²² cm⁻³ or more.

Furthermore, when the silicon nitride film 9 is disposed on the silicon substrate 1 with the silicon oxide film 7 therebetween, the difference in stress between silicon and the silicon nitride film can be reduced. The silicon oxide film 7 may be the same film as the gate insulating film 3. In such a case, the fabrication process can be further simplified.

In such a structure, the same film can function as the etch stop film for forming the contact hole and the antireflection film at the light-receiving surface of the photoelectric converting element. Consequently, it is possible to easily provide a photoelectric converter in which reflection at the light-receiving surface and dark current are reduced.

### Second Embodiment

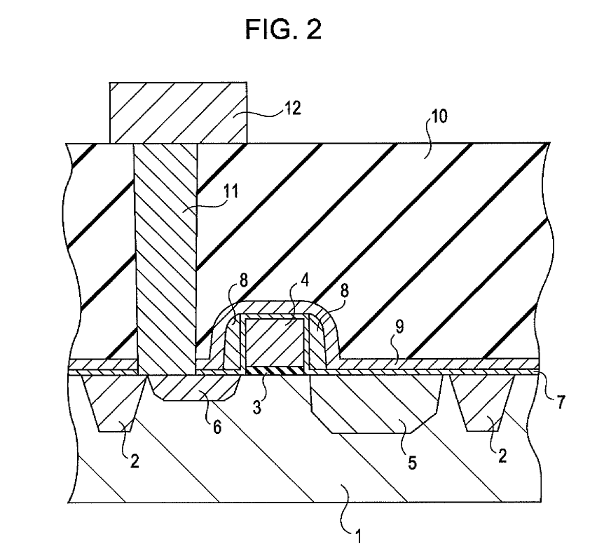

A second embodiment will be described with reference to FIG. 2. In FIG. 2, the parts having the same functions as those in the first embodiment shown in FIG. 1 are represented by the same reference numerals, and the description thereof will be omitted. This embodiment differs from the first embodiment in that a sidewall 8 is disposed on the side face of the gate electrode 4 with the silicon oxide film 7 therebetween. For example, a silicon nitride film is used as an insulating film for the sidewall 8.

That is, two types of insulating films (silicon oxide film 7 and silicon nitride films 8 and 9) are provided as a sidewall on the gate electrode 4. The difference in stress between the silicon nitride film 8 and the silicon substrate 1 or the gate electrode 4 is reduced by the silicon oxide film 7.

As in the first embodiment, the silicon nitride film 9 is arranged above at least the light-receiving surface of the photoelectric converting element and is arranged so as to cover the element isolation region 2 and the active region of the semiconductor in which the contact hole is formed. The sidewall 8 is also formed on the transistors other than the transistor in the pixel area.

### Third Embodiment

After the silicon nitride film 9, such as that shown in the first embodiment, which functions as the antireflection film and the etch stop film, is formed so as to cover the entire surface including a peripheral circuit portion, the silicon nitride film 9 is etched back only in the peripheral circuit portion. Thus, using the sidewalls composed of the resulting silicon nitride film, it is possible to allow the transistors in the peripheral circuit portion to have an LDD structure.

The peripheral circuit portion corresponds to scanning circuits for driving the MOS transistors and circuits for reading signals from the pixels. Examples include the clamp circuit, the column amplifier portion, the signal holding portion including the capacitors 112a and 112b, and the scanning circuits 119 and 123, which are shown in FIG. 4A.

The silicon nitride film 9 formed on the pixel area 124 is not subjected to etching and is protected with a mask or the like. By using such a structure, the performance of the transistors in the peripheral circuit portion can be improved while reducing etching damage to the photoelectric converting elements during the formation of sidewalls.

(Method for Fabricating Photoelectric Converter)

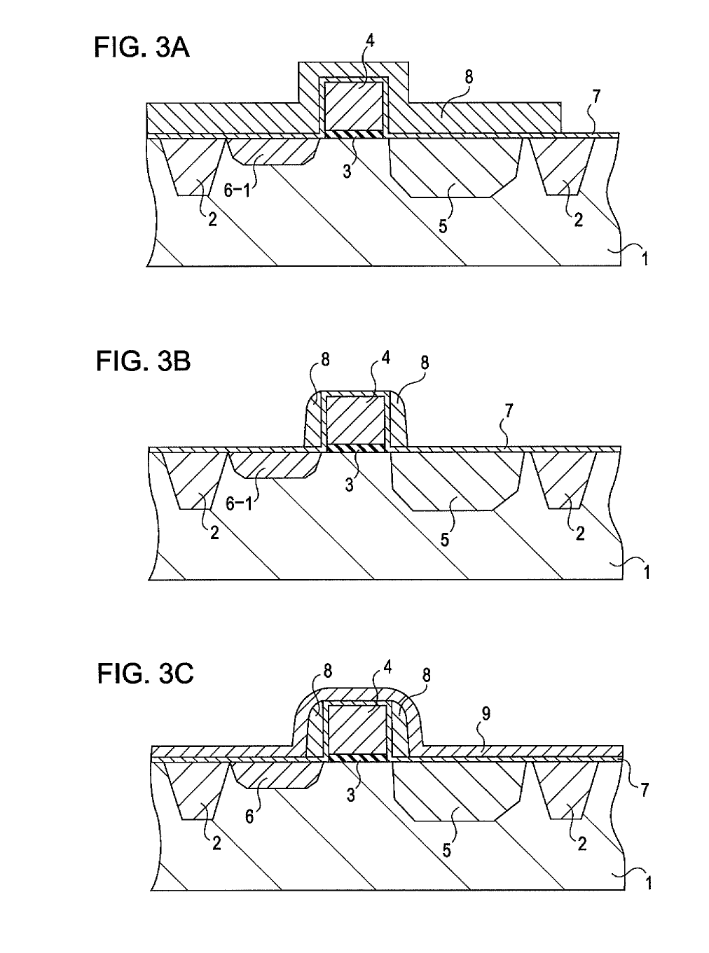

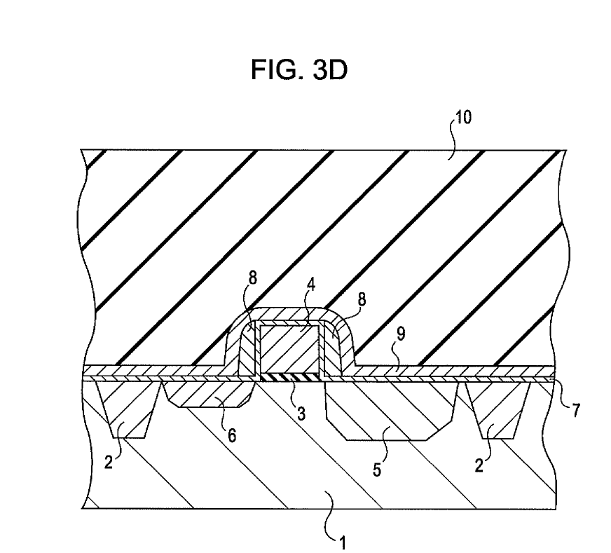

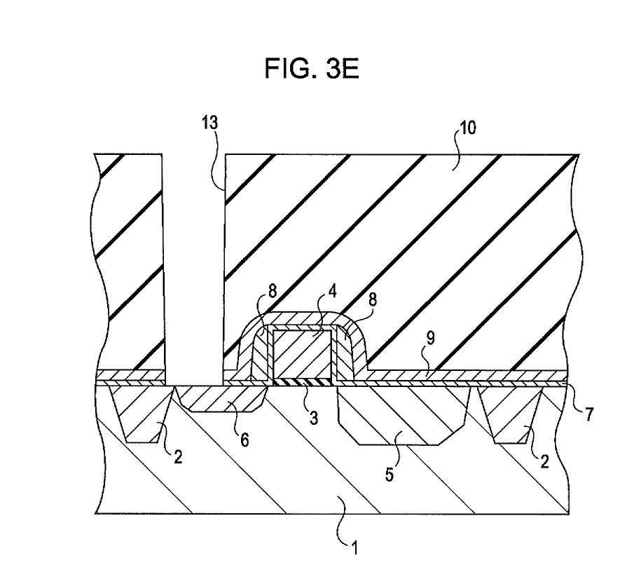

A method for fabricating a photoelectric converter will be described below with reference to FIGS. 3A to 3E.

First, as shown in FIG. 3A, a trench is formed on a first-conductivity-type silicon substrate 1. An insulating material is buried in the trench to form an element isolation region 2. Then, a gate insulating film 3 is formed, and a gate electrode 4 is formed by patterning. Subsequently, a second-conductivity-type semiconductor region 5 and a drain region 6-1 of a transfer MOS transistor are formed by ion implantation or the like. In this step, the gate electrode 4 is allowed to function as a mask against ion implantation. Subsequently, a silicon oxide film 7 is formed on the second-conductivity-type semiconductor region 5. Then, a silicon nitride film 8 is formed.

Next, as shown in FIG. 3B, the entire surface of the silicon nitride film 8 is etched back, and thus, a sidewall of the gate electrode 4 is formed. The etching-back is performed so that the silicon oxide film 7 remains on the surface of the silicon substrate 1. By allowing the silicon oxide film 7 to remain on the silicon substrate 1, it is possible to protect the photoelectric converting element from etching damage.

Referring to FIG. 3C, after the side wall is formed, a silicon nitride film 9 which functions as an antireflection film and an etch stop film is formed with a thickness of about 30 to 70 nm. The silicon nitride film 9 is formed so as to cover the semiconductor region 5 and cover at least the element isolation region 2 and the active region in which a contact is formed. The silicon nitride film 9 is disposed in such a manner in order to prevent the insulating material in the element isolation region 2 from being removed due to misalignment during etching for forming the contact hole. The silicon nitride film 9 may be disposed so as to cover the boundary between the active region in which the contact hole is formed and the element isolation region 2, or may be formed on the entire surface of the substrate.

In this step, in order to form a lightly doped drain (LDD) structure, before the formation of the silicon nitride film 9, a second-conductivity-type impurity is further implanted into the drain region 6-1 using the sidewall as a mask, to form a drain region 6. The LDD structure is not clearly shown in the drawing.

Furthermore, as shown in FIG. 3D, after the silicon nitride film 9 is formed, an interlayer insulating film 10 is formed. For example, a BPSG film is deposited as the interlayer insulating film 10, and planarization is performed by chemical mechanical polishing (CMP).

Subsequently, as shown in FIG. 3E, a contact hole 13 is formed at a predetermined position. The contact hole 13 is an opening formed by dry etching in the interlayer insulating film 10. First, the silicon nitride film 9 is compared with the interlayer insulating film 10, and an etching technique in which the interlayer insulating film 10 is selectively etched is chosen. Etching is performed until the hole formed by etching reaches the silicon nitride film 9. Thus, even if misalignment is caused by a technique in which the silicon oxide film and the silicon nitride film having different etching selectivities are combined, it is possible to reduce damage to the insulator, such as the silicon oxide film of the element isolation region 2. Subsequently, using a technique in which the silicon nitride film 9 is more easily etched than the insulator of the element isolation region 2, the depth of the contact hole is increased. By a known method, a metal is buried in the opening to form a plug and a contact 11. Subsequently, a wiring layer 12 is formed. The structure shown in FIG. 2 is thereby obtained.

In such a photoelectric converter, the antireflection film at the light-receiving portion of the photoelectric converting element and the etch stop film used when the contact hole is formed in the interlayer insulating film later can be formed in the same step using the same insulating film. Consequently, it is possible to simplify the process for forming the antireflection film and the etch stop film.

In the drawings, only the element isolation region 2 adjacent to the photoelectric converting element is shown. However, when the photoelectric converter has a plurality of MOS transistors, the silicon nitride film 9 may be formed in regions for isolating the MOS transistors from each other or isolating the photoelectric converting element from the MOS transistors. In such a case, problems resulting from misalignment of contact holes in the MOS transistors are reduced.

Furthermore, in the case where an LDD structure is not used as in the case shown in FIG. 1, without carrying out the step of forming the sidewall, the silicon nitride film 9 which functions as the antireflection film and the etch stop film is formed after the formation of the gate electrode.

(Application to Imaging System)

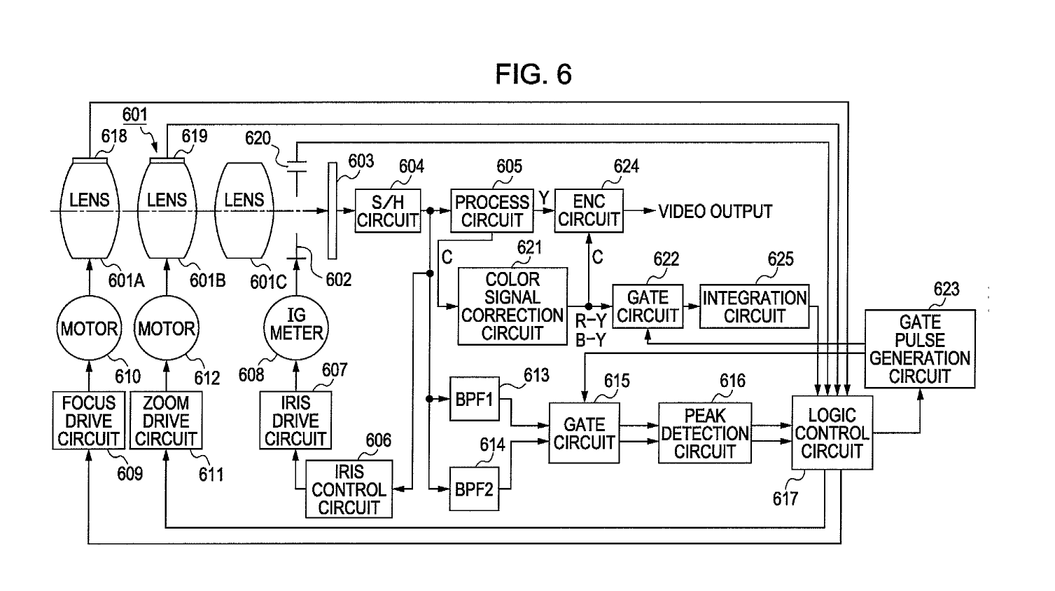

FIG. 6 is a block diagram showing a case where the photoelectric converter according to any of the embodiments described above is applied to a video camera, which is an example of an imaging system. Other examples of the imaging system include digital still cameras and the like. The video camera will be described in detail below with reference to FIG. 6.

A taking lens unit 601 includes a focus lens 601A for performing focusing, a zoom lens 601B for performing a zoom operation, and a lens 601C for forming an image. Reference numeral 602 represents an iris and a shutter, and reference numeral 603 represents a photoelectric converter which converts a subject image formed on the imaging area into electrical image signals. As the photoelectric converter 603, the photoelectric converter according to any of the embodiments described above is used. A sample/hold circuit (S/H circuit) 604 samples and holds the photoelectrically converted signals output from the photoelectric converter 603, further amplifies the level, and outputs video signals.

A process circuit 605 performs predetermined processes, such as gamma correction, color separation, and blanking, on the video signals output from the sample/hold circuit 604, and outputs luminance signals Y and chroma signals C. The chroma signals C output from the process circuit 605 are subjected to white balance correction and color balance correction by a color signal correction circuit 621, and output as color difference signals R-Y and B-Y. The luminance signals Y output from the process circuit 605 and the color difference signals R-Y and B-Y output from the color signal correction circuit 621 are modulated by an encoder circuit (ENC circuit) 624, and output as standard television signals. The standard television signals are supplied to a video recorder or an electronic view finder, such as a monitor electronic view finder (EVF) (not shown).

An iris control circuit 606 controls an iris drive circuit 607 on the basis of the video signals supplied from the sample/hold circuit 604. The iris drive circuit 607 automatically controls an IG meter 608 to control the aperture value of the iris 602 so as to obtain a predetermined video signal level.

Band-pass filters 613 and 614 extract high frequency-components required for focus detection from video signals output from the sample/hold circuit 604. Signals output from the first band-pass filter (BPF1) 613 and the second band-pass filter (BPF2) 614, which have different band limits, are gated by a gate circuit 615 driven by a gate pulse generation circuit 623 and a focus gate frame signal, and their peak values are detected and held by a peak detection circuit 616. The signals are input to a logic control circuit 617. These signals are referred to as focal point voltages, and the focus is adjusted based on the focal point voltages. Reference numeral 622 represents a gate circuit and reference numeral 625 represents an integration circuit.

A focus encoder 618 detects the moving position of the focus lens 601A. A zoom encoder 619 detects the in-focus state of the zoom lens 601B. An iris encoder 620 detects the aperture value of the iris 602. The values detected by these encoders are supplied to the logic control circuit 617 which performs system control.

The logic control circuit 617 performs focus detection with respect to a subject and the focus is adjusted based on the video signals corresponding to a selected in-focus detection area. That is, the logic control circuit 617 receives the peak value data of the high-frequency components supplied from the band-pass filters 613 and 614, and then drives focus lens 601A to a position where the peak value of the high-frequency component is maximized. For that purpose, the logic control circuit 617 supplies control signals of the rotation direction, rotation speed, rotation/stop, and the like of a focus motor 610 to a focus drive circuit 609, thus controlling the focus drive circuit 609.

A zoom drive circuit 611 rotates a zoom motor 612 when zooming is instructed. When the zoom motor 12 is rotated, the zoom lens 601B moves to perform a zoom operation.

By applying the photoelectric converter of the present invention to such an imaging system, it is possible to provide an imaging system having a high S/N ratio in which reflection of light and dark current are reduced.

As described above, according to the present invention, it is possible to provide higher-performance photoelectric converters and imaging systems in which reflection of light at the photoelectric converting elements and dark current are reduced. The materials and the fabrication method are not limited to those of the individual embodiments, and the conductivity type of the semiconductor substrate and the structure of the pixel are not limited to those described above. For example, the element isolation region may have a LOCOS structure or the like beside the STI structure. The formation range of the etch stop film is not limited to that of the embodiments.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

This application claims the benefit of Japanese Application No. 2005-330142 filed Nov. 15, 2005, which is hereby incorporated by reference herein in its entirety.

What is claimed is:

1. A photoelectric converter comprising:
a substrate;
photoelectric converting elements formed in the substrate and each having a light-receiving surface;
an antireflection film arranged above at least a part of the light-receiving surface of each photoelectric converting element;
an element isolation region including an insulator;
a plurality of transistors including read transistors configured to read electric charges of the photoelectric converting elements;
an interlayer insulating film arranged above the photoelectric conversion elements and the read transistors; and
contacts electrically connected to active regions of the transistors,
wherein the antireflection film is arranged above the element isolation region and the active region connected to each contact, and
the antireflection film serves as an etch stop film when the interlayer insulating film is etched.

2. The photoelectric converter according to claim 1, wherein the insulator and the interlayer insulating film are each composed of silicon oxide, and the antireflection film is composed of silicon nitride.

3. The photoelectric converter according to claim 1, further comprising an insulating film disposed between the light-receiving surface and the antireflection film.

4. The photoelectric converter according to claim 3, wherein the insulating film serves as a gate insulating film of each read transistor.

5. The photoelectric converter according to claim 1, wherein the antireflection film is disposed on the substrate so as to cover gate electrodes of the plurality of transistors.

6. The photoelectric converter according to claim 1, wherein gate electrodes of at least some of the plurality of transistors have sidewalls, each sidewall including an insulating film, a sidewall insulating film disposed on the insulating film, and the antireflection film, the sidewall insulating film being composed of a material that is different from that of the insulating film.

7. The photoelectric converter according to claim 6, wherein the insulating film is further disposed between the light-receiving surface and the antireflection film.

8. The photoelectric converter according to claim 6, wherein the sidewall insulating film comprises silicon nitride.

9. The photoelectric converter according to claim 1, wherein the antireflection film is composed of a silicon nitride film having a hydrogen concentration of 1×10²² cm⁻³ or more.

10. An imaging system comprising:
the photoelectric converter according to claim 1;
an optical system configured to focus light on the photoelectric converter; and
a signal processing circuit configured to process output signals from the photoelectric converter.

11. A photoelectric converter comprising:
a substrate;
photoelectric converting elements formed in the substrate and each having a light-receiving surface;
an antireflection film arranged above at least a part of the light-receiving surface of each photoelectric converting element;
an element isolation region including an insulator;
a plurality of transistors including read transistors configured to read electric charges of the photoelectric converting elements;
an interlayer insulating film arranged above the photoelectric conversion elements and the read transistors; and
contacts electrically connected to active regions of the transistors,
wherein the antireflection film is arranged above the element isolation region and the active region connected to each contact, and
an opening for each contact is formed in the interlayer insulating film using the antireflection film as an etch stop film.
